(19) United States
(12) Patent Application Publication
(10) Pub. No.: US 2025/0183010 A1
(43) Pub. Date: Jun. 5, 2025

(54) THERMAL PLASMA ETCHING SYSTEM AND THERMAL PLASMA ETCHING METHOD

(71) Applicant: Metal Industries Research & Development Centre, Kaohsiung (TW)

(72) Inventors: Wei-Chen Tien, Chiayi City (TW); Cheng-Yuan Hung, Kaohsiung City (TW); Ping Tun Huang, Changhua County (TW)

(73) Assignee: Metal Industries Research & Development Centre, Kaohsiung (TW)

(21) Appl. No.: 18/523,926

(22) Filed: Nov. 30, 2023

(51) Int. Cl. H01J 37/32

(52) U.S. Cl. CPC H01J 37/32522; H01J 37/3244; H01J 37/32623; H01J 2237/3345

(57) ABSTRACT

A thermal plasma etching system is adapted to etch an object and includes a gas source, a plasma source, a heating module, a vacuum chamber, a diffuser plate, and an electrode plate. The plasma source is communicated with the gas source, for dissociating the gas and generating a plasma. The heating module is communicated with the plasma source for heating the plasma to a thermal plasma. The heating module is disposed between the plasma source and the vacuum chamber, and the thermal plasma is adapted to enter the vacuum chamber. The diffusion disk is disposed in the vacuum chamber. The electrode plate is disposed in the vacuum chamber and separated from the diffusion disk by a distance. The object is adapted to be placed on the electrode plate, the thermal plasma diffuses from the diffusion disk to the electrode plate to etch the object on the electrode plate.

### BACKGROUND

### Technical Field

The present invention relates to a thermal plasma etching system and a thermal plasma etching method, and in particular to a thermal plasma etching system and a thermal plasma etching method that can increase the etching rate of the object, reduce the surface roughness of the object after being etched and have better anisotropic etching characteristic of the object after being etched.

### Description of Related Art

Because the silicon carbide substrate has a lower chemical reaction rate, the etching rate of the silicon carbide substrate is quite low by using the conventional plasma etching system. In addition, the surface roughness and the anisotropic characteristic of the silicon carbide substrate after being etched by the conventional plasma etching system also have poor performance. Therefore, how to improve the etching rate and provide a lower surface roughness and a better anisotropic characteristic of the object after being etched are the goals of the field.

### SUMMARY

The present invention provides a thermal plasma etching system and a thermal plasma etching method, which can increase the etching rate of the object, reduce the surface roughness of the object after being etched and have better anisotropic etching characteristic of the object after being etched.

The present invention is a thermal plasma etching system is adapted to etch an object and includes a gas source, a plasma source, a heating module, a vacuum chamber, a diffuser plate, and an electrode plate. The gas source is adapted for providing a gas. The plasma source is communicated with the gas source, for dissociating the gas and generating a plasma. The heating module is communicated with the plasma source for heating the plasma to a thermal plasma. The heating module is disposed between the plasma source and the vacuum chamber, and the thermal plasma is adapted to enter the vacuum chamber. The diffusion disk is disposed in the vacuum chamber. The electrode plate is disposed in the vacuum chamber and separated from the diffusion disk by a distance. The object is adapted to be placed on the electrode plate, the thermal plasma diffuses from the diffusion disk to the electrode plate to etch the object on the electrode plate.

In an embodiment of the present invention, the diffusion disk and the electrode plate are configured in parallel.

In an embodiment of the present invention, the distance is between 15 mm and 40 mm.

In an embodiment of the present invention, the heating module includes a heating pipe, and the heating pipe is provided with a porous honeycomb structure and/or a fin.

In an embodiment of the present invention, the heating module includes a heating pipe, and a length of the heating pipe is between 5 cm and 30 cm, so that a temperature of the thermal plasma is between 100° C. and 500° C.

In an embodiment of the present invention, the plasma source further includes a pressurized element.

In an embodiment of the present invention, the thermal plasma passing through the diffusion disk maintains an ionization state.

In an embodiment of the present invention, the heating module comprises a heating pipe, and a length of the heating pipe is between 5 cm and 30 cm.

The present invention is a thermal plasma etching method includes following steps:

providing a plasma; heating the plasma to become a thermal plasma; and sending the thermal plasma to a diffusion disk in a vacuum chamber, such that the thermal plasma is diffused to an electrode plate to etch an object located on the electrode plate.

In an embodiment of the present invention, in a step of sending the thermal plasma to the diffusion disk in the vacuum chamber, a temperature of the thermal plasma is between 100° C. and 500° C.

In an embodiment of the present invention, before the step of sending the thermal plasma to the diffusion disk in the vacuum chamber, the thermal plasma etching method further comprises accelerating the thermal plasma.

In an embodiment of the present invention, the thermal plasma passing through the diffusion disk maintains an ionization state.

In an embodiment of the present invention, in a step of heating the plasma, the plasma is heated for less than 10 seconds.

In an embodiment of the present invention, in a step of heating the plasma, the plasma passes through a heating pipe to become the thermal plasma, and the heating pipe is provided with a porous honeycomb structure and/or a fin.

In an embodiment of the present invention, the diffusion disk and the electrode plate are configured in parallel.

In an embodiment of the present invention, a distance between the diffusion disk and the electrode plate is between 15 mm and 40 mm.

Based on the above, in the thermal plasma etching system and thermal plasma etching method of the present invention, the plasma generated by the plasma source is heated to the thermal plasma through the heating module, and the thermal plasma is used to etch the object located on the electrode plate. This design can increase the etching rate of the object, reduce the surface roughness of the object after being etched and obtain the better anisotropic etching characteristic of the object after being etched.

### BRIEF DESCRIPTION OF THE DRAWINGS

FIG. 1 is a schematic diagram of a thermal plasma etching system according to an embodiment of the present invention.

FIG. 2 is a schematic diagram of a thermal plasma etching method according to an embodiment of the present invention.

FIG. 3A is a sectional schematic diagram of a heating pipe along the AA section line of the thermal plasma etching system in FIG. 1.

FIG. 3B is a sectional schematic diagram of a heating pipe according to another embodiment of the present invention.

FIG. 4A is an intensity-time relationship diagram of spectrum analysis of conventional plasma.

FIG. 4B is an intensity-time relationship diagram of spectrum analysis of the thermal plasma in FIG. 2.

FIG. 5 is an intensity-time relationship diagram of spectrum analysis for argon plasma and fluorine plasma at different temperatures.

FIG. 6 is a schematic diagram of etching depths of an object in the conventional plasma etching system and the thermal plasma etching system in FIG. 1.

FIG. 7A is a surface etching topography of the object after being etched by the conventional plasma etching system.

FIG. 7B is a surface etching topography of the object after being etched by the thermal plasma etching system in FIG. 1 whose temperature of the thermal plasma is 100° C.

FIG. 7C is a surface etching topography of the object after being etched by the thermal plasma etching system in FIG. 1 whose temperature of the thermal plasma is 300° C.

### DESCRIPTION OF THE EMBODIMENTS

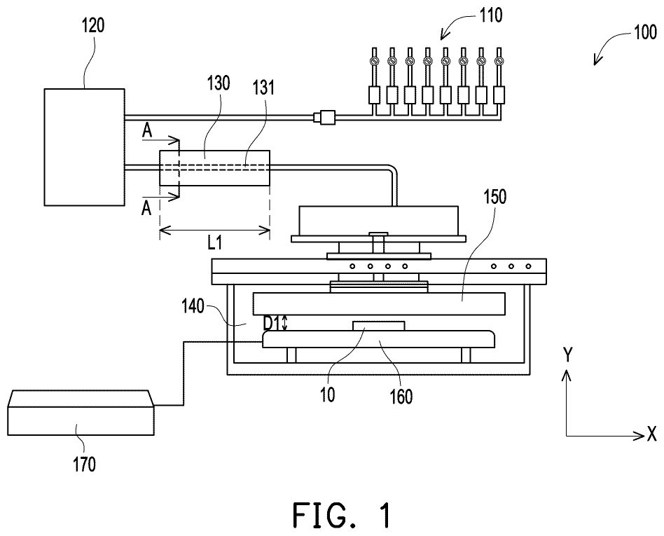

FIG. 1 is a schematic diagram of a thermal plasma etching system according to an embodiment of the present invention. Referring to FIG. 1, a thermal plasma etching system 100 of the embodiment is adapted for etching an object 10. The thermal plasma etching system 100 includes a gas source 110, a plasma source 120, a heating module 130, a vacuum chamber 140, a diffusion disk 150 and an electrode plate 160. The gas source 110 is adapted to provide a gas. The plasma source 120 is communicated with the gas source 110 for dissociating the gas and generating a plasma. The heating module 130 is communicated with the plasma source 120 to heat the plasma to a thermal plasma. The heating module 130 is disposed between the plasma source 120 and the vacuum chamber 140, and the thermal plasma is adapted for entering the vacuum chamber 140. The diffusion disk 150 is disposed in the vacuum chamber 140. The electrode plate 160 is disposed in the vacuum chamber 140 and connected to the power supply 170. The electrode plate 160 is separated from the diffusion disk 150 by a distance D1. The object 10 is adapted for being placed on the electrode plate 160. The thermal plasma diffuses from the diffusion disk 150 to the electrode plate 160 to etch the object 10 located on the electrode plate 160.

In this embodiment, the gas provided by the gas source 110 is nitrogen trifluoride (NF₃) and argon gas (Ar). A ratio of nitrogen trifluoride (NF₃) and argon gas (Ar) is 1:1, and a gas flux of each of nitrogen trifluoride (NF₃) and argon gas (Ar) is 2SLM. The process pressure is between 0.1˜50 Torr. However, the gas type, the gas flux and the process pressure are not limited thereto.

In addition, in this embodiment, the plasma source 120 is a Remote Plasma Source (RPS), but a type of plasma source 120 is not limited thereto. In other embodiments, the plasma source 120 can also be an Inductively Coupled Plasma (ICP) source.

On the other hand, in this embodiment, a frequency of the plasma source 120 is 400 KHz, and a radio frequency power of the plasma source 120 is 1000 W. A frequency of the electrode plate 160 is 40.68 MHz, and a radio frequency power of the electrode plate 160 is 400 W. In other embodiments, the frequency of the plasma source 120 can also be, for example, 13.56 MH, 40.68 MHz, or any frequency between 100 KHz and 40 MHz, and the frequency of the electrode plate 160 can also be any frequency between 100 KHz and 40 MHz. The frequencies and the radio frequency powers of the plasma source 120 and the electrode plate 160 are not limited thereto.

A material of the object 10 of the embodiment may include silicon carbide (SiC), other compound semiconductor materials, or any combination of the foregoing materials, but the material of the object 10 is not limited to. It can be known that the object 10 of the embodiment can also be other objects which has a desired surface topography by plasma etching, the type of the object 10 is not limited thereto.

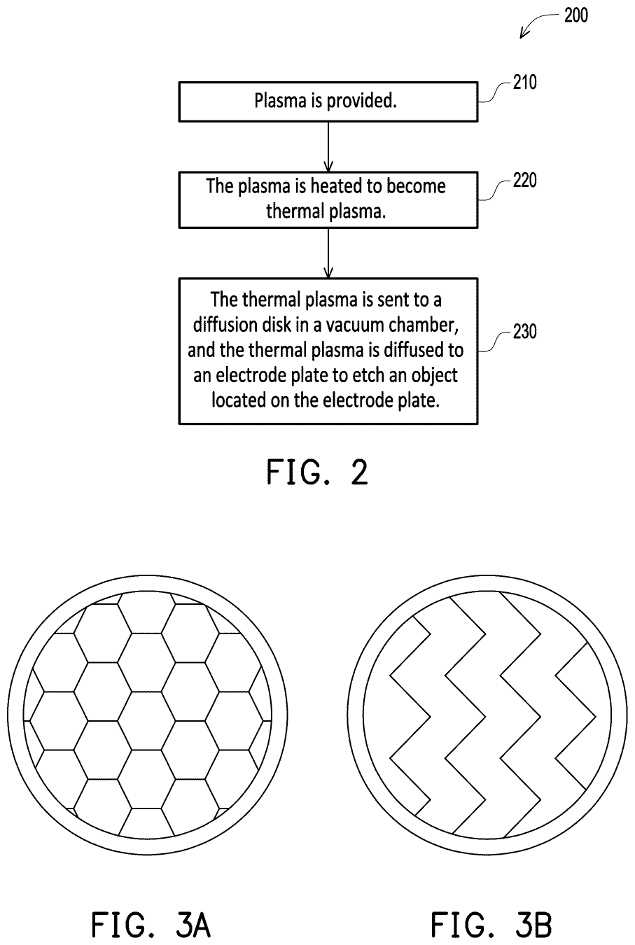

FIG. 2 is a schematic diagram of a thermal plasma etching method according to an embodiment of the present invention. Referring to FIG. 2, a thermal plasma etching method 200 of the embodiment includes the following steps. First, in step 210, the thermal plasma etching system 100 provides a gas through the gas source 110, and the plasma source 120 is communicated with the gas source 110 for dissociating the gas to provide a plasma. Then, in step 220, the thermal plasma etching system 100 heats the plasma through the heating module 130, so that the plasma becomes a thermal plasma. Finally, in step 230, in the thermal plasma etching system 100, the thermal plasma is sent to the diffusion disk 150 in the vacuum chamber 140, and the thermal plasma is diffused to the electrode plate 160 to etch the object 10 located on the electrode plate 160.

The thermal plasma etching system 100 and thermal plasma etching method 200 of the embodiment heats the plasma generated by the plasma source 120 through the heating module 130 to become the thermal plasma, so as to enhance the ion capability of the thermal plasma and make the ion of the thermal plasma have higher bombardment energy. Such a design can improve the etching rate of the object 10 etched by the thermal plasma, reduce the surface roughness of the object 10 after being etched, and improve the anisotropic etching characteristic of the object 10, thereby improving the performance of object 10.

Please refer to FIG. 1, in this embodiment, in a Y-axis direction, the diffusion disk 150 is located above the electrode plate 160, and the diffusion disk 150 and the electrode plate 160 are configured in parallel. That is to say, normal directions of the diffusion disk 150 and the electrode plate 160 are parallel to the Y axis. In addition, a distance D1 between the diffusion disk 150 and the electrode plate 160 is between 15 mm and 40 mm, but the distance D1 between the diffusion disk 150 and the electrode plate 160 is not limited thereto. In some embodiments, when the distance D1 is between 15 mm and 40 mm, the thermal plasma passing through the diffusion disk 150 can be diffused more efficiently to etch the object 10, and the anisotropic etching characteristic of the object 10 can be improved.

In addition, the heating module 130 includes a heating pipe 131, a length L1 of the heating pipe 131 is between 5 cm and 30 cm, and the time for the plasma to be heated by the heating pipe 131 is less than 10 seconds, so as to make the temperature of the thermal plasma is between 100° C. and 500° C. The design can effectively increase the etching rate of the object 10, reduce the surface roughness of the object 10 after being etched and improve the anisotropic etching characteristic of the object 10.

It is worth to mention that because the length L1 of the heating pipe 131 is between 5 cm and 30 cm, and the time of heating the plasma is less than 10 seconds, the thermal plasma etching system 100 can more effectively reduce the possibility that the thermal plasma returns to a steady state due to the long heating time.

It should be noted that the thermal plasma etching system 100 can also use other ways to control the time of heating the plasma, such as adding a pressurizer (not shown) to the plasma source 120 to increase the speed of the plasma passing through the heating pipe 131, so that the plasma can be heated to the target temperature quickly without returning to the stable state. The method of controlling the time of heating the plasma is not limited thereto.

On the other hand, it is noted that the position of the heating module 130 is not limited to the position shown in FIG. 1. The heating module 130 can be disposed in any position between the plasma source 120 and the vacuum chamber 140. Preferably, the temperature of the thermal plasma which is sent to the vacuum chamber 140 is between 100° C. and 500° C.

FIG. 3A is a sectional schematic diagram of a heating pipe along the AA section line of the thermal plasma etching system in FIG. 1. FIG. 3B is a sectional schematic diagram of a heating pipe according to another embodiment of the present invention. It should be noted that the heating device around the heating pipe 131 is not illustrated in FIG. 3A and FIG. 3B. Please refer to FIG. 3A first, in this embodiment, the heating pipe 131 of the heating module 130 is provided with a porous honeycomb structure. However, the structure in the heating pipe 131 is not limited thereto. In other embodiments, the heating pipe 131 can also be equipped with fins as shown in FIG. 3B, any other structure that can increase the thermal exchange rate of the plasma or any combination of the aforementioned structures can be applied to the heating pipe 131. The structure in the heating pipe 131 is not limited thereto.

It is worth to mention that the thermal plasma etching system 100 is equipped with the porous honeycomb structure and/or the fins in the heating pipe 131 to increase the thermal exchange rate between the plasma generated by the plasma source 120 and the heating pipe 131, thereby reducing the time of heating the plasma. This design can reduce the probability that the thermal plasma returns to the stable state due to the long heating time.

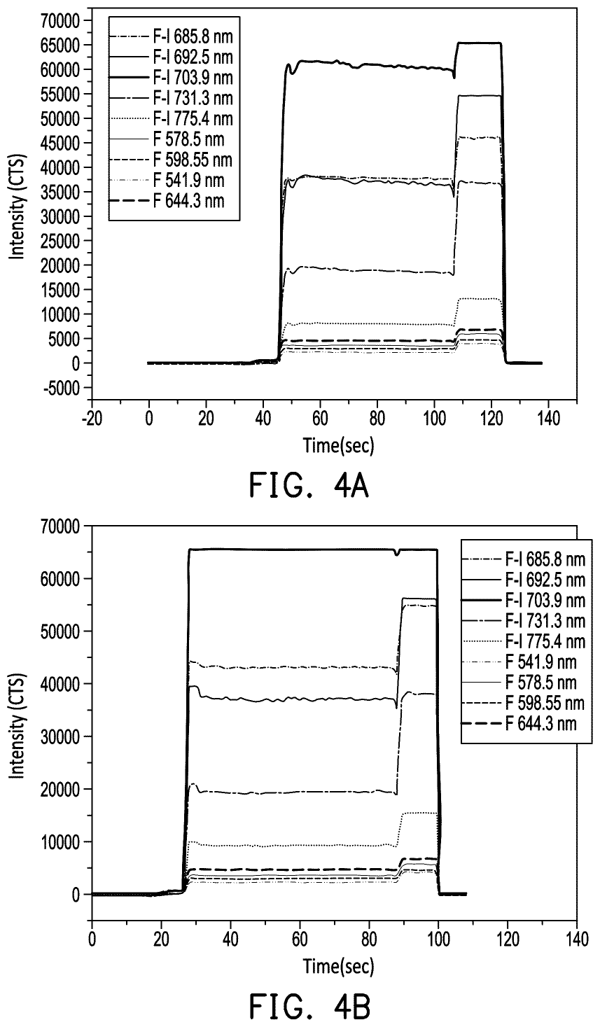

FIG. 4A is an intensity-time relationship diagram of spectrum analysis of conventional plasma. FIG. 4B is an intensity-time relationship diagram of spectrum analysis of the thermal plasma in FIG. 2. It should be noted that FIG. 4A and FIG. 4B are respectively intensity-time diagrams of conventional plasma and the thermal plasma of FIG. 2 after observation by a plasma spectrum analyzer (Optical Emission Spectroscopy, OES). Please refer to FIG. 4A and FIG. 4B, compared with the conventional plasma, the fluorine plasma of the thermal plasma of the embodiment has a significant improvement in the intensity of the emission spectrum at 703.9 nm and 685.8 nm. The enhancement ratios are 8.3% and 12% respectively. It represents that the total amount of gas dissociation and energy of the thermal plasma increase.

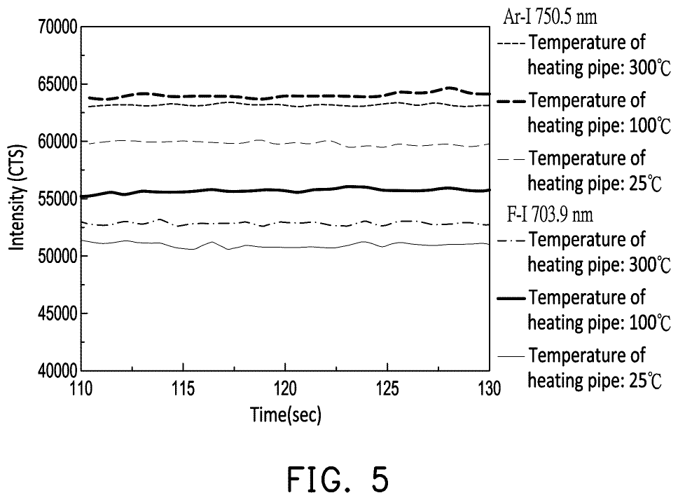

FIG. 5 is an intensity-time relationship diagram of spectrum analysis for argon plasma and fluorine plasma at different temperatures. Please refer to FIG. 5, the intensity of fluorine plasma and argon plasma which are heated to 100° C. or 300° C. is greater than the intensity of fluorine plasma and argon plasma whose temperature is 25° C. It means that when the temperature of the plasma is higher, both of the total gas dissociation and the energy of the plasma increase.

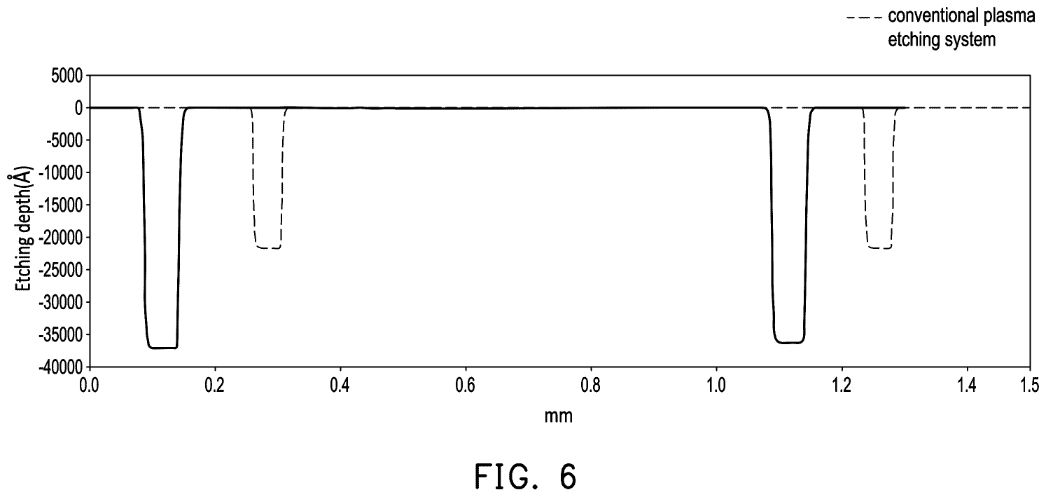

FIG. 6 is a schematic diagram of etching depths of an object in the conventional plasma etching system and the thermal plasma etching system in FIG. 1. It should be noted that after object 10 is etched, the surface etching depth can be obtained by the surface profiler, and then the etching rate can be obtained by the depth and the total etching time. Please refer to FIG. 6, the surface etching depth of the object 10 after being etched by the conventional plasma etching system for 5 minutes is 21650 Å, and the etching rate can be converted as 0.43 mm/min. In addition, the surface etching depth of the object 10 after being etched by the thermal plasma etching system 100 of the embodiment for 5 minutes is 37150 Å, and the etching rate can be converted as 0.74 mm/min. In other words, the thermal plasma etching system 100 of the embodiment has a greater etching rate.

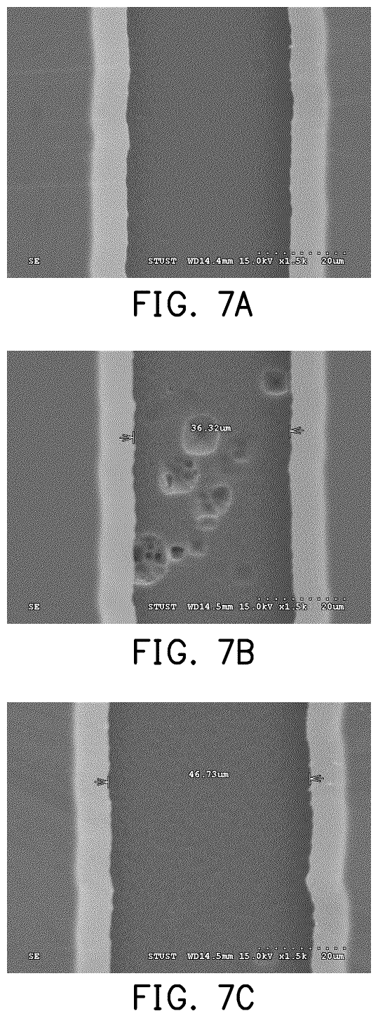

FIG. 7A is a surface etching topography of the object after being etched by the conventional plasma etching system. FIG. 7B is a surface etching topography of the object after being etched by the thermal plasma etching system in FIG. 1 whose temperature of the thermal plasma is 100° C. FIG. 7C is a surface etching topography of the object after being etched by the thermal plasma etching system in FIG. 1 whose temperature of the thermal plasma is 300° C. Please refer to FIGS. 7A to 7C, in the embodiment, the temperature of the heating module 130 of the thermal plasma etching system 100 can be adjusted, so that the thermal plasma can have different temperatures, the surface topography and characteristic of the object 10 can be adjusted accordingly. In addition, in other embodiments, the surface topography and characteristic of the object 10 can be adjusted by adjusting the gas ratio of the thermal plasma etching system 100.

To sum up, in the thermal plasma etching system and thermal plasma etching method of the present invention, the plasma generated by the plasma source is heated to the thermal plasma through the heating module, and the thermal plasma is used to etch the object located on the electrode plate. This design can increase the etching rate of the object, reduce the surface roughness of the object after being etched and obtain the better anisotropic etching characteristic of the object after being etched. In addition, in the thermal plasma etching system and thermal plasma etching method, the thermal exchange rate between the plasma and the heating pipe can be increased by applying the porous honeycomb structure or the fins to the heating pipe of the heating module. Moreover, in an embodiment of the thermal plasma etching system and the thermal plasma etching method, the length of the heating pipe is between 5 cm and 30 cm, and the time of heating the plasma is less than 10 seconds, such that the probability of the thermal plasma returning to the stable state can be reduced.

What is claimed is:

1. A thermal plasma etching system, adapted for etching an object, comprising:
a gas source, adapted for providing a gas;
a plasma source, communicated with the gas source, for dissociating the gas and generating a plasma;
a heating module communicated with the plasma source for heating the plasma to a thermal plasma;
a vacuum chamber, wherein the heating module is disposed between the plasma source and the vacuum chamber, and the thermal plasma is adapted to enter the vacuum chamber;
a diffusion disk, disposed in the vacuum chamber; and
an electrode plate, disposed in the vacuum chamber and separated from the diffusion disk by a distance, wherein the object is adapted to be placed on the electrode plate, the thermal plasma diffuses from the diffusion disk to the electrode plate to etch the object on the electrode plate.

2. The thermal plasma etching system as claimed in claim 1, wherein the diffusion disk and the electrode plate are configured in parallel.

3. The thermal plasma etching system as claimed in claim 2, wherein the distance is between 15 mm and 40 mm.

4. The thermal plasma etching system as claimed in claim 1, wherein the heating module comprises a heating pipe, and the heating pipe is provided with a porous honeycomb structure and/or a fin.

5. The thermal plasma etching system as claimed in claim 1, wherein when the thermal plasma enters the vacuum chamber, a temperature of the thermal plasma is between 100° C. and 500° C.

6. The thermal plasma etching system as claimed in claim 5, wherein the plasma source further includes a pressurized element.

7. The thermal plasma etching system as claimed in claim 5, wherein the thermal plasma passing through the diffusion disk maintains an ionization state.

8. The thermal plasma etching system as claimed in claim 5, wherein the heating module comprises a heating pipe, and a length of the heating pipe is between 5 cm and 30 cm.

9. A thermal plasma etching method, comprising:
providing a plasma;
heating the plasma to become a thermal plasma; and
sending the thermal plasma to a diffusion disk in a vacuum chamber, such that the thermal plasma is diffused to an electrode plate to etch an object located on the electrode plate.

10. The thermal plasma etching method as claimed in claim 9, wherein in a step of sending the thermal plasma to the diffusion disk in the vacuum chamber, a temperature of the thermal plasma is between 100° C. and 500° C.

11. The thermal plasma etching method as claimed in claim 10, wherein before the step of sending the thermal plasma to the diffusion disk in the vacuum chamber, the thermal plasma etching method further comprises accelerating the thermal plasma.

12. The thermal plasma etching method as claimed in claim 10, wherein the thermal plasma passing through the diffusion disk maintains an ionization state.

13. The thermal plasma etching method as claimed in claim 10, wherein in a step of heating the plasma, the plasma is heated for less than 10 seconds.

14. The thermal plasma etching method as claimed in claim 9, wherein in a step of heating the plasma, the plasma passes through a heating pipe to become the thermal plasma, and the heating pipe is provided with a porous honeycomb structure and/or a fin.

15. The thermal plasma etching method as claimed in claim 9, wherein the diffusion disk and the electrode plate are configured in parallel.

16. The thermal plasma etching method as claimed in claim 15, wherein a distance between the diffusion disk and the electrode plate is between 15 mm and 40 mm.
